(19) United States
(12) Patent Application Publication
(10) Pub. No.: US 2025/0187493 A1
(43) Pub. Date: Jun. 12, 2025

(54) METHOD FOR CHARGING A MAINTENANCE BATTERY BY A PROPULSION BATTERY.

(71) Applicant: Scania CV AB, Södertälje (SE)

(72) Inventors: Per NORDVALL, Trosa (SE); Gunnar LEDFELT, Nykvarn (SE); Viktor NYMAN, Bandhagen (SE); Börje NILSSON, Järna (SE)

(73) Assignee: Scania CV AB, Södertälje (SE)

(21) Appl. No.: 18/845,989

(22) PCT Filed: Mar. 22, 2023
(86) PCT No.: PCT/SE2023/050250

§ 371 Date: Sep. 11, 2024

(30) Foreign Application Priority Data
Mar. 29, 2022 (SE) 2250384-1

(51) Int. Cl. B60L 58/20; B60L 58/13; B60L 58/16

(52) U.S. Cl. CPC B60L 58/20; B60L 58/13; B60L 58/16; B60L 2240/545; B60L 2240/547; B60L 2240/549; B60L 2250/10

(57) ABSTRACT

The application relates to charging a maintenance battery pack of a vehicle, which also comprises a propulsion battery pack, comprising, when the vehicle is inactive: providing a predetermined threshold SOC/SOH1_{Threshold} value when charging is activated and a predetermined threshold SOH2_{Threshold} value when charging is terminated; continually measuring maintenance battery pack voltage, current, and temperature; calculating State Of Charge SOC, as number of ampere hours possible to discharge before the maintenance battery pack is discharged; calculating State of Health SOH, as number of ampere hours possible to discharge if the maintenance battery pack was fully charged; calculating a battery charge quota SOC/SOH; comparing SOC/SOH with the SOC/SOH1_{Threshold} value; if SOC/SOH<SOC/SOH1_{Threshold}, checking the condition of the propulsion battery pack, and if condition is satisfactory, activating the propulsion battery pack to charge the maintenance battery, comparing SOC/SOH with the SOC/SOH2_{Threshold} value; and terminating charging when SOC/SOH≥SOC/SOH2_{Threshold}.

### TECHNICAL AREA

The present application relates to a method and system for handling low voltage battery packs in vehicles and in particular vehicles provided with electric propulsion.

### BACKGROUND OF INVENTION

The development of electrically operated vehicles is increasing rapidly due mainly to environmental aspects. Electrically operated vehicles comprise vehicles that have one or several electrical motors that work together with combustion engines, so called hybrid vehicles. At the same time, fully electrically operated vehicles gain much attention and development due to the very low emission levels during operation and charging.

Many of the electrically operated vehicles are provided with one or several large battery packs that provide energy for the propulsion of the vehicle. These propulsions batteries often operate with high voltages, in the range between 48-1000 V. In addition, many such vehicles that are larger, such as trucks, lorries, busses and the like also are provided with maintenance battery packs that operate with lower voltages, usually in the region 12-48 V. These maintenance battery packs are arranged for operating functions of the vehicle that are not powered by the propulsion batteries, such as for instance control units, auxiliary or customized units and driver equipment. One important function of the maintenance battery packs is to provide energy for the activation of the vehicle and the connection of the propulsion battery packs.

During operation of the vehicle, the maintenance battery pack may be charged by a power source of the vehicle such as an alternator or a DC/DC-converter. When the vehicle comes to a standstill and an inactivation of the propulsion battery pack, the maintenance battery pack is still in function to keep many of the vehicle systems active. In order to be able to securely maintain the function of the vehicle systems during inactivated vehicle, the maintenance battery pack has to be dimensioned to handle time periods until charging, which time periods may be quite long. The maintenance battery packs are for that reason somewhat over-dimensioned, and even so there is a risk that more energy is used that is available in the maintenance battery pack, leading to that the vehicle cannot be started, even if there is enough energy in the propulsion battery packs. This in turn gives that the maintenance battery packs become rather large and heavy, which negatively affects the load capacity of the vehicle.

### BRIEF DESCRIPTION OF INVENTION

The aim of the present application is to handle maintenance battery packs of the above-mentioned kind so that the risk of discharging the maintenance battery is minimized. In the following, the wording “continually” will be used. In this context, continually is to be understood to comprise actions and functions that either are performed without interruption, i.e. continuously or during certain time intervals, i.e. sampling of data.

According to one aspect of the application, a method is provided for charging a maintenance battery pack of a vehicle, which vehicle comprises a propulsion battery pack and a maintenance battery pack. When the vehicle is inactive, the method performs the steps of providing a predetermined first threshold value as a value when charging is activated and a predetermined second threshold value as a value when charging is terminated.

Battery voltage, battery current and battery temperature of the maintenance battery pack may be continually measured. From the measurements, battery charge level, State Of Charge, SOC, may be calculated as number of ampere hours possible to discharge before the maintenance battery pack is discharged. Also, battery health, State of Health, SOH, may be calculated as number of ampere hours possible to discharge if the maintenance battery pack was fully charged as well as calculating a value of battery charge quota SOC/SOH.

The battery charge value is then compared with the predetermined first threshold value. The battery charge quota is lower than the first threshold, the condition of the propulsion battery pack is checked, and if condition is satisfactory, the propulsion battery pack is activated to charge the maintenance battery. During charging, the battery charge quota is compared with the predetermined second threshold value and when the battery charge value reaches or exceeds the second threshold value, the charging is terminated.

The solution has the advantage that the propulsion battery pack can be used to charge the maintenance battery pack during situations where the vehicle is parked and inactive and is not connected to a stationary charging station. This increases the safety against discharging the maintenance battery pack to such an extent that the vehicle cannot be activated or started. This in turn has the advantage that the size of the maintenance battery pack can be reduced and thereby the weight, allowing the vehicle to carry more goods and load.

According to one aspect, the first threshold value and the second threshold value are the last values obtained before the vehicle was set inactive. The part of the control system that provides the threshold values may be inactivated when the vehicle is not in operation, which otherwise could provide the threshold values continually. The method then uses the last information before inactivation of the vehicle.

As a further measure the condition of the propulsion battery pack during charging of the maintenance battery pack may be checked, and if the condition has reached a predetermined lowest value, charging of the maintenance battery pack is terminated. This measure ascertains that the propulsion battery pack is not discharged too much so that it might jeopardize the propulsion of the vehicle.

Also, denying charging may be the situation also before charging of the maintenance battery pack if the condition of propulsion battery pack is below a predetermined lowest value. Other parameters such as temperature, cell voltage etc, may cause a denying of charging. This situation may be communicated by alerting a person handling the vehicle that charging of the maintenance battery pack is denied. An advantageous value of the condition of the propulsion battery pack may be based on the SOC of the propulsion battery pack. As an alternative or addition for terminating charging could be when a maximum permissible charging time has been reached.

According to a further aspect of the application, the method may comprise further steps, when the vehicle is active. These may comprise providing a predetermined first threshold value as a value when charging is activated and a predetermined second threshold value as a value when charging is terminated. Battery voltage, battery current and battery temperature of the maintenance battery pack may be continually measured and State Of Charge and State Of Health are calculated based on the measurements, as well as a value of battery charge level.

The battery charging level is then compared with the predetermined first threshold value; and if the battery charging level is lower than the first threshold value, a power source of the vehicle is activated to charge the maintenance battery pack preferably by transferring electric energy from propulsion battery via a DC/DC-converter. During charging, the battery charge value is compared with the predetermined second threshold value, and the charging is terminated when the battery charging level reaches or exceeds the second threshold value.

These and other aspects of, and advantages with, the present invention will become apparent from the following detailed description of the invention and from the accompanying drawings.

### BRIEF DESCRIPTION OF DRAWINGS

In the following detailed description of the invention, reference will be made to the accompanying drawings, of which

FIG. 1 is a schematic view of a vehicle comprising a system for handling charging of a maintenance battery pack,

FIG. 2 is a flow chart of the communication between control units of the system and the steps of charging during active vehicle, and

FIG. 3 is a flow chart of the communication between control units of the system and the steps of charging during inactive vehicle.

### DETAILED DESCRIPTION OF THE INVENTION

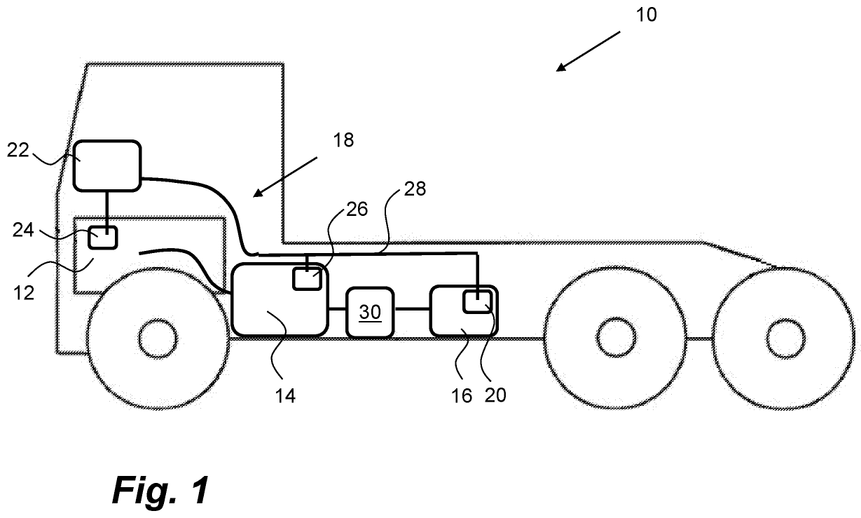

A vehicle 10 comprising an aspect of the application is shown in FIG. 1. The vehicle 10 comprises a propulsion engine 12, preferably an electric motor or machine. The electric machine 12 could be working together with a combustion engine, a hybrid vehicle, or be the single power source, a fully electric vehicle. A propulsion battery pack 14 is provided in the vehicle 10 and electrically connected to the propulsion engine 12 for providing energy necessary for driving the vehicle 10. The electric machine 12 is further preferably capable of generating electric power when the vehicle is retarding, providing regenerating charging of the propulsion battery. Suitable systems are provided for controlling the energy between the propulsion engine and the propulsion battery pack 14, the functions of which will not be described in detail.

The vehicle 10 is further provided with a maintenance battery pack 16 that is electrically connected to an electric control system 18 of the vehicle, for handling equipment and functions that requires lower voltages. The control system 18 comprises control units, driver equipment and battery handling. More particularly the control units of the control system 18 may comprise a battery data module 20, a chassis control unit 22, an electric machine unit 24 and a propulsion battery handling unit 26, the functions of which will be described below. The modules and the units of the control system are provided with communication devices that enable communication between them via a communication circuit 28 and with appropriate communication protocols such as CAN. Further, a power source such as a DC/DC-converter 30 is electrically connected between the propulsion battery 14 and the auxiliary battery 16.

In the following a description of a method of charging the maintenance battery pack will be described.

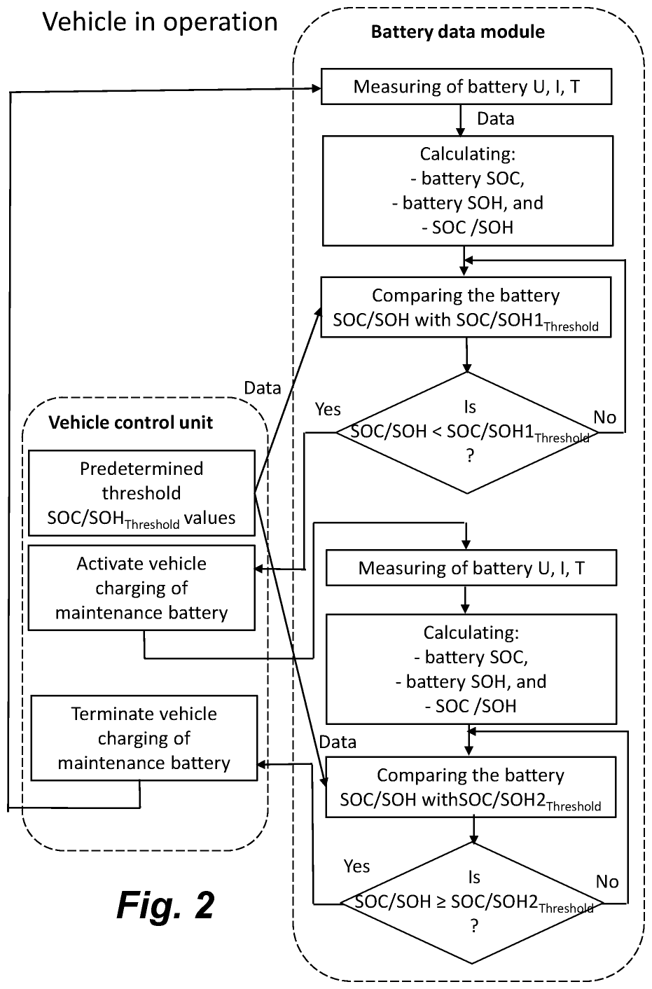

### Vehicle in Operation, FIG. 2

When the vehicle is in operation, the battery data module 20 is continually obtaining data regarding the maintenance battery 16 via suitable sensors that can measure voltage, current and temperature. The battery data module 20 is provided with memory elements and processor units for storing and handling of the incoming data. The processor unit is arranged to calculate a battery charge level, State Of Charge (SOC), as a value of the number of ampere hours that are possible to discharge until the battery is discharged. The processor unit is further arranged to calculate the health of the maintenance battery, State Of Health (SOH), as a value of the number of ampere hours that are possible to discharge as if the battery was fully charged. The battery data module then calculates a value of battery charge quota SOC/SOH. This is done continually. The chassis control unit 22 is provided with storage elements in which pre-determined threshold values of SOC/SOH_{Threshold} are stored. At least two SOC/SOH_{Threshold} values are stored in the chassis control module 22, a first SOC/SOH1_{Threshold} value for initiating a charging of the maintenance battery pack 16 and a second SOC/SOH2_{Threshold} value for terminating charging of the maintenance battery pack 16. One of these values is continually transmitted to the battery data module 20 when the vehicle is active and in operation, as will be described.

The battery data module will continually compare the calculated value of SOC/SOH quota with the SOC/SOH_{Threshold} value. If the maintenance battery pack is not being charged, the first SOC/SOH1_{Threshold} value is transmitted to the battery data module. If the comparison shows that the SOC/SOH quota value is below SOC/SOH1_{Threshold}, i.e. SOC/SOH<SOC/SOH1_{Threshold}, the battery data module 20 will send a command to the chassis control unit 22 to activate and to initiate a charging of the maintenance battery pack. The charging may be performed by a DC/DC-converter 30 of the vehicle. When the charging has started, the chassis control unit 22 will transmit the second SOC/SOH2_{Threshold} value to the battery data module. As mentioned, the battery data module continually calculates the SOC/SOH quota values and compares it with the SOC/SOH2_{Threshold} value. If the comparison shows that the SOC/SOH quota value has increased such that it has reached or is above SOC/SOH2_{Threshold} due to the charging, i.e. SOC/SOH>SOC/SOH2_{Threshold}, the battery data module 20 will send a command to the chassis control unit 22 to activate and to terminate the charging of the maintenance battery pack 16. The above-mentioned process will continue as long as the vehicle is in operation.

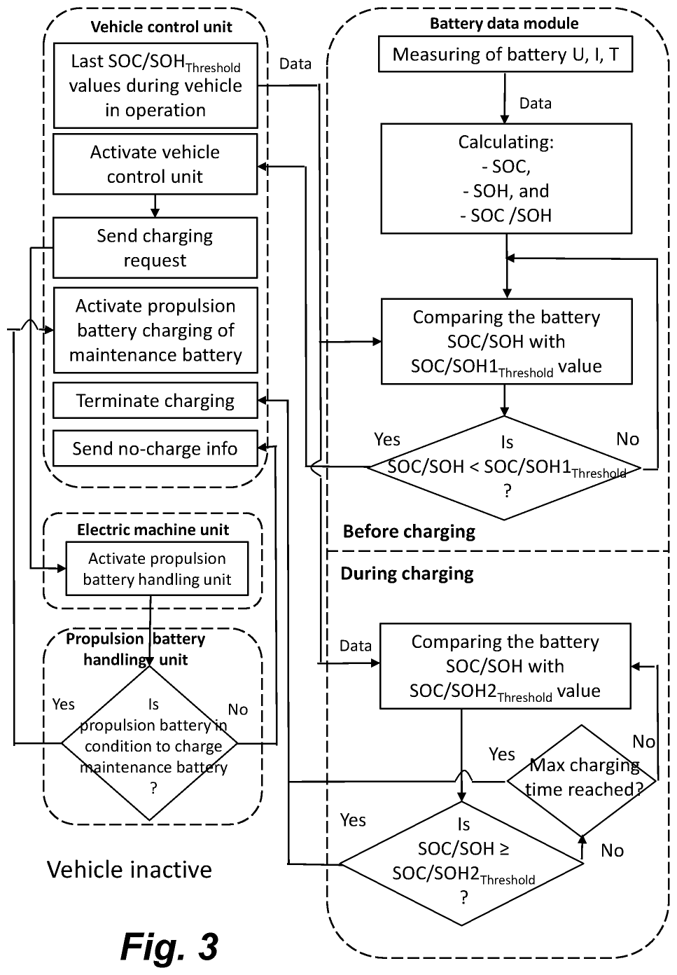

### Vehicle inactive, FIG. 3

When the vehicle is stopped and inactivated, the chassis control unit 22 is set in a sleep mode. The battery data module 20 however continues to monitor the maintenance battery pack 16 and will calculate the SOC/SOH quota value of the maintenance battery pack. The battery data module 20 will compare the calculated quota value with the latest transmitted SOC/SOH1_{Threshold} value obtained when the chassis control unit 22 was active. If the comparison shows that the SOC/SOH quota value has decreased below the SOC/SOH1_{Threshold} value, i.e. SOC/SOH<SOC/SOH1_{Threshold}, the battery data module 20 transmits a wake-up command to the chassis control unit 22. The chassis control unit 22 will in turn wake up affected units for sending a request for charging message via the communication circuit 28 to the electric machine unit 24. The electric machine unit 24 then wakes up the battery handling unit 26 for the propulsion battery pack 14. The battery handling unit 26 for the propulsion battery pack performs a status and health check of the propulsion battery 14. If the check is positive, charging of the maintenance battery pack 16 from the propulsion battery pack 14 is initiated.

During charging, the battery data module 20 continues to calculate the SOC/SOH quota value of the maintenance battery pack 16 and compares the quota value with the last transmitted second threshold value SOC/SOH2_{Threshold} when the chassis control unit 22 was active. If the comparison shows that the SOC/SOH quota value has increased such that it has reached or is above SOC/SOH2_{Threshold} due to the charging, i.e. SOC/SOH>SOC/SOH2_{Threshold}, the battery data module 20 will send a command to the chassis control unit 22 to activate and to terminate the charging of the maintenance battery pack 16.

The charging may also be terminated if the battery handling unit 26 for the propulsion battery pack considers that the status and health of the propulsion battery pack 14 has become such that it is no longer safe to discharge the propulsion battery pack 14, for instance if the SOC of the propulsion battery pack 14 is too low. This is also the case if the request for charging is sent from the chassis control unit 22 to the handling unit 26 for the propulsion battery pack 14 and the SOC of the propulsion battery pack 14 is too low. The request is in this case denied and no charging will take place. A signal may be sent to a display in the cabin of the vehicle to inform the driver that no charge of the maintenance battery pack 16 is taking place.

As an alternative or in addition to comparing the SOC/SOH quota value of the maintenance battery pack with the SOC/SOH2_{Threshold} value, the charging period may be set to a predefined charging time, after which the charging is terminated. Also here, the charging may be terminated in advance if the status and health of the propulsion battery pack 14 has become such that it is no longer safe to discharge the propulsion battery pack 14.

It is to be understood that the embodiment described above and shown in the drawings is to be regarded only as a non-limiting example of the invention and that it may be modified in many ways within the scope of the patent claims.

1. A method of charging a maintenance battery pack of a vehicle, which vehicle comprises a propulsion battery pack and a maintenance battery pack, said method comprising the steps of, when the vehicle is inactive:
providing a predetermined first threshold value SOC/SOH1_{Threshold} as a value when charging is activated and a predetermined second threshold value SOC/SOH2_{Threshold} as a value when charging is terminated;
continually measuring battery voltage, battery current, and battery temperature of the maintenance battery pack;
calculating, based on the measurements, battery charge level, State Of Charge SOC, as number of ampere hours possible to discharge before the maintenance battery pack is discharged;
calculating, based on the measurements, battery health, State of Health SOH, as number of ampere hours possible to discharge, if the maintenance battery pack was fully charged;
calculating SOC/SOH as a value of battery charge quota; and
comparing the battery charge quota SOC/SOH with the predetermined first threshold SOC/SOH1_{Threshold} value;
if SOC/SOH<SOC/SOH1_{Threshold},
checking the condition of the propulsion battery pack, and if condition is satisfactory,
activating the propulsion battery pack to charge the maintenance battery,
comparing the battery charge quota SOC/SOH with the predetermined second threshold SOC/SOH2_{Threshold} value; and
terminating charging when SOC/SOH≥SOC/SOH2_{Threshold}.

2. A method according to claim 1, wherein the first threshold value SOH1_{Threshold} and the second threshold value SOH2_{Threshold} are the last values obtained before the vehicle was set inactive.

3. A method Method according to claim 1, further comprising:
checking the condition of the propulsion battery pack during charging of the maintenance battery pack, and if condition has reached a predetermined lowest value, terminating charging of the maintenance battery pack.

4. A method according to claim 1, wherein, if condition of propulsion battery pack is below a predetermined lowest value, denying charging of the maintenance battery pack.

5. A method according to claim 4, further comprising alerting a person handling the vehicle that charging of the maintenance battery pack is denied.

6. A method according to claim 3, wherein the condition of the propulsion battery pack is based on the SOC of the propulsion battery pack.

7. A method Method according to claim 1, wherein charging is terminated when SOC/SOH>SOC/SOH2_{Threshold} or when a maximum permissible charging time has been reached.

8. A method according to claim 1, comprising the further steps, when the vehicle is active:
providing a predetermined first threshold value SOC/SOH1_{Threshold} as a value when charging is activated and a predetermined second threshold value SOC/SOH2_{Threshold} as a value when charging is terminated;
continually measuring battery voltage, battery current and battery temperature of the maintenance battery pack;
calculating, based on the measurements, SOC and SOH;
calculating SOC/SOH as a value of battery charge quota;
comparing the battery charge quota SOC/SOH with the predetermined first threshold SOC/SOH1_{Threshold} value; and if SOC/SOH<SOC/SOH1_{Threshold}, activating a power source of the vehicle to charge the maintenance battery pack;
comparing the battery charge quota SOC/SOH with the predetermined second threshold SOC/SOH2_{Threshold} value; and
terminating charging when SOC/SOH≥SOC/SOH2_{Threshold}.

9. A computer program product stored on a non-transitory computer-readable medium, said computer program product for charging a maintenance battery pack of a vehicle, which vehicle comprises a propulsion battery pack and a maintenance battery pack, wherein said computer program product comprising computer instructions to cause one or more computing devices to perform the following operations, when the vehicle is inactive:
providing a predetermined first threshold value SOC/SOH1_{Threshold} as a value when charging is activated and a predetermined second threshold value SOC/SOH2_{Threshold} as a value when charging is terminated;
continually measuring battery voltage, battery current, and battery temperature of the maintenance battery pack;
calculating, based on the measurements, battery charge level, State Of Charge SOC, as number of ampere hours possible to discharge before the maintenance battery pack is discharged;
calculating, based on the measurements, battery health, State of Health SOH, as number of ampere hours possible to discharge, if the maintenance battery pack was fully charged;
calculating SOC/SOH as a value of battery charge quota; and
comparing the battery charge quota SOC/SOH with the predetermined first threshold SOC/SOH1_{Threshold} value;
if SOC/SOH<SOC/SOH_{Threshold},
checking the condition of the propulsion battery pack, and if condition is satisfactory,
activating the propulsion battery pack to charge the maintenance battery comparing the battery charge quota SOC/SOH with the predetermined second threshold SOC/SOH2_{Threshold} value; and
terminating charging when SOC/SOH≥SOC/SOH2_{Threshold}.

10. (canceled)

11. A system for charging a an maintenance battery pack of a vehicle, which vehicle comprises a propulsion battery pack and a an maintenance battery pack, the system comprising:
a control unit provided with sensors and arranged to measure battery voltage, battery current and battery temperature of the maintenance battery pack;
the control unit being provided with means for:
calculating, based on the measurements, battery charge level, State Of Charge SOC, as number of ampere hours possible to discharge before the maintenance battery pack is discharged;
calculating, based on the measurements, battery health, State of Health SOH, as number of ampere hours possible to discharge if the maintenance battery pack was fully charged;
calculating SOC/SOH as a value of battery charge quota;
the control unit further provided with a predetermined first threshold SOC/SOH1_{Threshold} value as a value when charging is activated and a predetermined second threshold value SOC/SOH2_{Threshold} as a value when charging is terminated; and
the control unit being arranged to compare the battery charge quota SOC/SOH with the predetermined first threshold SOC/SOH1_{Threshold} value when the vehicle is inactive;
if SOC/SOH<SOC/SOH1_{Threshold},
the control unit being arranged to check the condition of the propulsion battery pack, and if condition is satisfactory,
the control unit being arranged to activate the propulsion battery pack to charge the maintenance battery,
the control unit being arranged to compare the battery charge quota SOC/SOH with the predetermined second threshold SOC/SOH2_{Threshold} value; and
wherein the control unit is arranged to terminate charging when SOC/SOH≥SOC/SOH2_{Threshold}.

12. A system according to claim 11, wherein:
the control unit being arranged to compare the battery charge quota SOC/SOH with the predetermined first threshold SOC/SOH1_{Threshold} value when the vehicle is active;
if SOC/SOH<SOC/SOH1_{Threshold},
the control unit being arranged to activate a power source of the vehicle to charge the maintenance battery,
the battery data module being arranged to compare the battery charge quota SOC/SOH with the predetermined second threshold SOC/SOH2_{Threshold} value; and
wherein the control unit is arranged to terminate charging when SOC/SOH≥SOC/SOH2_{Threshold}.

13. A system according to claim 11, wherein the control unit comprises a battery data module, a chassis control unit, an electric machine unit (and a propulsion battery handling unit.

14. A vehicle provided with a system for charging a maintenance battery pack of a vehicle, which vehicle comprises a propulsion battery pack and a maintenance battery pack, the system comprising:
a control unit provided with sensors and arranged to measure battery voltage, battery current and battery temperature of the maintenance battery pack;
the control unit being provided with means for:
calculating, based on the measurements, battery charge level, State Of Charge SOC, as number of ampere hours possible to discharge before the maintenance battery pack is discharged;
calculating, based on the measurements, battery health, State of Health SOH, as number of ampere hours possible to discharge if the maintenance battery pack was fully charged;
calculating SOC/SOH as a value of battery charge quota;
the control unit further provided with a predetermined first threshold SOC/SOH1_{Threshold} value as a value when charging is activated and a predetermined second threshold value SOC/SOH2_{Threshold} as a value when charging is terminated; and
the control unit being arranged to compare the battery charge quota SOC/SOH with the predetermined first threshold SOC/SOH1_{Threshold} value when the vehicle is inactive;
if SOC/SOH<SOC/SOH1_{Threshold},
the control unit being arranged to check the condition of the propulsion battery pack, and if condition is satisfactory,
the control unit being arranged to activate the propulsion battery pack to charge the maintenance battery,
the control unit being arranged to compare the battery charge quota SOC/SOH with the predetermined second threshold SOC/SOH2_{Threshold} value; and
wherein the control unit is arranged to terminate charging when SOC/SOH≥SOC/SOH2_{Threshold}.

15. A vehicle according to claim 14, wherein the vehicle is a fully electric propulsion vehicle or an electric and combustion engine propulsion vehicle.
